(19) United States
(12) Patent Application Publication
(10) Pub. No.: US 2006/0138633 A1
(43) Pub. Date: Jun. 29, 2006

(54) Semiconductor device

(75) Inventors: Mikio Naruse, Isehara-shi (JP); Akihiro Shibuya, Zama-shi (JP); Motoyuki Furukawa, Machida-shi (JP); Yasuhiro Okada, Sagamihara-shi (JP); Daigo Ueno, Zama-shi (JP)

Correspondence Address: FOLEY AND LARDNER LLP;SUITE 500, 3000 K STREET NW, WASHINGTON, DC, 20007, US

(73) Assignee: NISSAN MOTOR CO., LTD.

(21) Appl. No.: 11/317,078

(22) Filed: Dec. 27, 2005

(30) Foreign Application Priority Data
Dec. 28, 2004 (JP) 2004-379444

(51) Int. Cl. H01L 23/48

(52) U.S. Cl. 257/688

(57) ABSTRACT

A semiconductor device includes first and second semiconductor chips formed with electrodes on front and reverse sides, a first bus bar on which the first semiconductor chip is mounted so as the reverse side electrode to be connected thereto, a second bus bar, arranged parallel with the first bus bar, on which the second semiconductor chip is mounted so as the reverse side electrode to be connected thereto, a third bus bar that is press-connected to the front side electrode of the first semiconductor chip, a fourth bus bar that is press-connected to the front side electrode of the second semiconductor chip, and a connecting section that electrically connects the first bus bar and the fourth bus bar.

### INCORPORATION BY REFERENCE

The disclosure of the following priority application is herein incorporated by reference: Japanese Patent Application No. 2004-379444 filed Dec. 28, 2004

### BACKGROUND OF THE INVENTION

1. Field of the Invention

The present invention relates to a press-contact type semiconductor device.

2. Description of Related Art

Insulated gate bipolar transistors (IGBT) are employed as power switching devices for inverter devices for, for example, electric cars. With a semiconductor device disclosed in Japanese Patent Laid-open Publication No. 2001-110985, upper and lower arms employed in an inverter circuit are put into modular form and a P bus bar, N bus bar and output bus bar are arranged on the same surface. An upper arm IGBT chip is mounted at the P bus bar, and a lower arm IGBT chip is mounted at the output bus bar. An emitter electrode for the upper arm IGBT chip and the P bus bar, and an emitter electrode for the lower arm IGBT chip and the N bus bar are connected respectively using wire.

### SUMMARY OF THE INVENTION

However, the module for the above semiconductor device becomes large in order to enable the three bus bars to be arranged in the same plane. Further, in the event that the bus bars and semiconductor elements (IGBT chips) are connected using wire, it is necessary to connect a number of wires to each chip and the operation of connecting these wires is detrimental to the productivity rate.

A semiconductor device according to a first aspect of the present invention includes a first semiconductor chip formed with a front side electrode and a reverse side electrode, a second semiconductor chip formed with a front side electrode and a reverse side electrode, a first bus bar on which the first semiconductor chip is mounted so as the reverse side electrode of the first semiconductor chip to be connected thereto, a second bus bar, arranged horizontally with respect to the first bus bar, on which the second semiconductor chip is mounted so as the reverse side electrode of the second semiconductor chip to be connected thereto, a third bus bar that is press-connected to the front side electrode of the first semiconductor chip, a fourth bus bar that is press-connected to the front side electrode of the second semiconductor chip, and a connecting section that electrically connects the first bus bar and the fourth bus bar.

A semiconductor device according to a second aspect of the present invention includes a first semiconductor chip formed with a front side electrode and a reverse side electrode, a second semiconductor chip formed with a front side electrode and a reverse side electrode, a first bus bar on which the first semiconductor chip is mounted so as the reverse side electrode of the first semiconductor chip to be connected thereto, and on which the second semiconductor chip is mounted so as the front side electrode of the second semiconductor chip to be connected thereto, a second bus bar that is press-connected to the front side electrode of the first semiconductor chip, and a third bus bar that is press-connected to the reverse side electrode of the second semiconductor chip.

A semiconductor device according to a third aspect of the present invention includes a first semiconductor chip formed with a front side electrode and a reverse side electrode, a second semiconductor chip formed with a front side electrode and a reverse side electrode, a first bus bar on which the first semiconductor chip is mounted so as the reverse side electrode of the first semiconductor chip to be connected thereto, a second bus bar, arranged horizontally with respect to the first bus bar, on which the second semiconductor chip is mounted so as the reverse side electrode of the second semiconductor chip to be connected thereto, a first conductive member that connects with the front side electrode of the first semiconductor chip and comprises an extending section extending beyond the first semiconductor chip, a second conductive member that connects with the front side electrode of the second semiconductor chip and comprises an extending section extending to above the first bus bar, a third bus bar, arranged at a front surface side of the first semiconductor chip, with a part press-connected to the extending section of the first conductive member, and a fourth bus bar, arranged at a front surface side of the second semiconductor chip, with a part connected with the extending section of the second conductive member and press-connected to the first bus bar.

A semiconductor device according to a fourth aspect of the present invention includes first, second, third and fourth semiconductor chips formed with electrodes on front and reverse sides, a first bus bar on which the first and second semiconductor chips are mounted so as the reverse side electrodes to be connected hereto, a second bus bar, arranged horizontally with respect to the first bus bar, on-which the third and fourth semiconductor chips are mounted so as the reverse side electrodes to be connected thereto, a third bus bar that is press-connected to the front side electrodes of the first and second semiconductor chips, a fourth bus bar that is press-connected to the front side electrodes of the. third and fourth semiconductor chips, a connecting section that electrically connects the first bus bar and the fourth bus bar, a first pressing member arranged on the third bus bar so as to press the third bus bar towards the first semiconductor chip, a second pressing member arranged on the third bus bar so as to press the third bus bar towards the second semiconductor chip, a third pressing member arranged on the fourth bus bar so as to press the fourth bus bar towards the third semiconductor chip and a fourth pressing member arranged on the fourth bus bar so as to press the fourth bus bar towards the fourth semiconductor chip.

### BRIEF DESCRIPTION OF DRAWINGS

FIG. 1 shows a single phase inverter circuit, showing a first embodiment of a semiconductor device of the present invention.

FIG. 2A to FIG. 2C are views showing an external appearance of the semiconductor device fitted to a main cooling section, where FIG. 2A is a plan view, FIG. 2B is a front view; and FIG. 2C is a side view.

FIG. 3 is a cross-sectional view along A-A of FIG. 2A.

FIG. 4 is a perspective view showing a casing for each unit.

FIG. 5 is a perspective view of a bus bar.

FIG. 6 is a view showing a comparative example for a first embodiment.

FIGS. 7A to 7C are views showing an example of a bent section provided at a connection section.

FIG. 8 is a view showing a modified example of an electrode plate.

FIG. 9 is a view showing a modified example of an auxiliary cooling member.

FIG. 10 is a plan view of the auxiliary cooling member.

FIG. 11 is a cross-sectional view of a second embodiment of a semiconductor device of the present invention.

FIG. 12 is a perspective view showing a casing.

FIG. 13 is a perspective view showing a unit.

FIG. 14 is a plan view of a third embodiment of a semiconductor device of the present invention.

FIG. 15 is a cross-sectional view along C-C of FIG. 14.

FIG. 16A is a cross-sectional view along D-D of FIG. 14, and FIG. 16B is a cross-sectional view along E-E of FIG. 14.

FIG. 17A to FIG. 17C are views showing each unit of the third embodiment, where FIG. 17A is a plan view of a bottom unit, FIG. 17B is a plan view of a middle unit, and FIG. 17C is a plan view of a top unit.

FIG. 18 is a cross-sectional view of a fourth embodiment of a semiconductor device of the present invention.

FIG. 19 is an enlarged view of section G of FIG. 18.

FIG. 20 is a view showing a modified example of the fourth embodiment.

FIG. 21 is a circuit diagram of a three-phase inverter.

FIG. 22 is a plan view showing a bottom unit.

FIGS. 23A and 23B are views showing each unit corresponding to that of the fourth embodiment where FIG. 23A is a plan view of a middle unit and FIG. 23B is a plan view of a top unit.

FIG. 24 is a cross-sectional view of a fifth embodiment of a semiconductor device of the present invention.

FIG. 25 is a view illustrating the operation of an auxiliary cooling member.

FIG. 26A and FIG. 26B a reviews illustrating the operation of suppressing an unbalanced load, where FIG. 26A shows the case where C1>C2 (S1<S2), and FIG. 26B shows the case where C1<C2 (S1>S2) FIG. 27A to FIG. 27D are views showing a modified example of a buffer member.

### DESCRIPTION OF PREFERRED EMBODIMENTS

The following is a description with reference to the drawings of a preferred embodiment of the present invention.

### First Embodiment

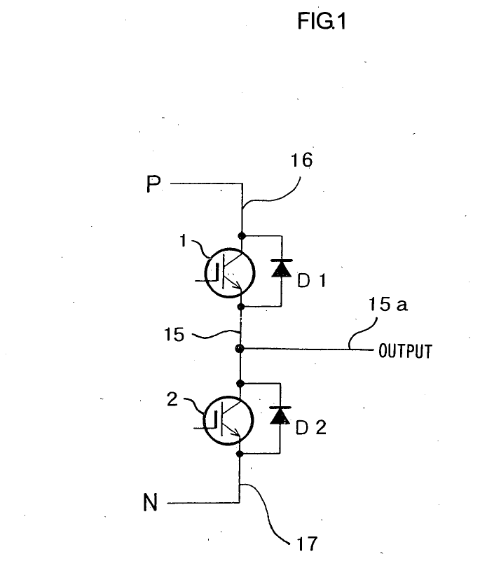

FIG. 1 is a view showing a first embodiment of a semiconductor device of the present invention, and is a single phase inverter circuit. IGBT and MOSFETs etc. are taken as switching elements used in inverters and FIG. 1 shows the single-phase inverter employing IGBT's 1 and 2 and diodes D1 and D2. An emitter electrode of upper arm IGBT 1 is connected to a collector electrode of lower arm IGBT 2, and an output is taken from between this emitter and collector. Further, the collector electrode of the IGBT 1 is connected to a P-side of a power supply and the emitter electrode of the IGBT 2 is connected to a N-side of the power supply.

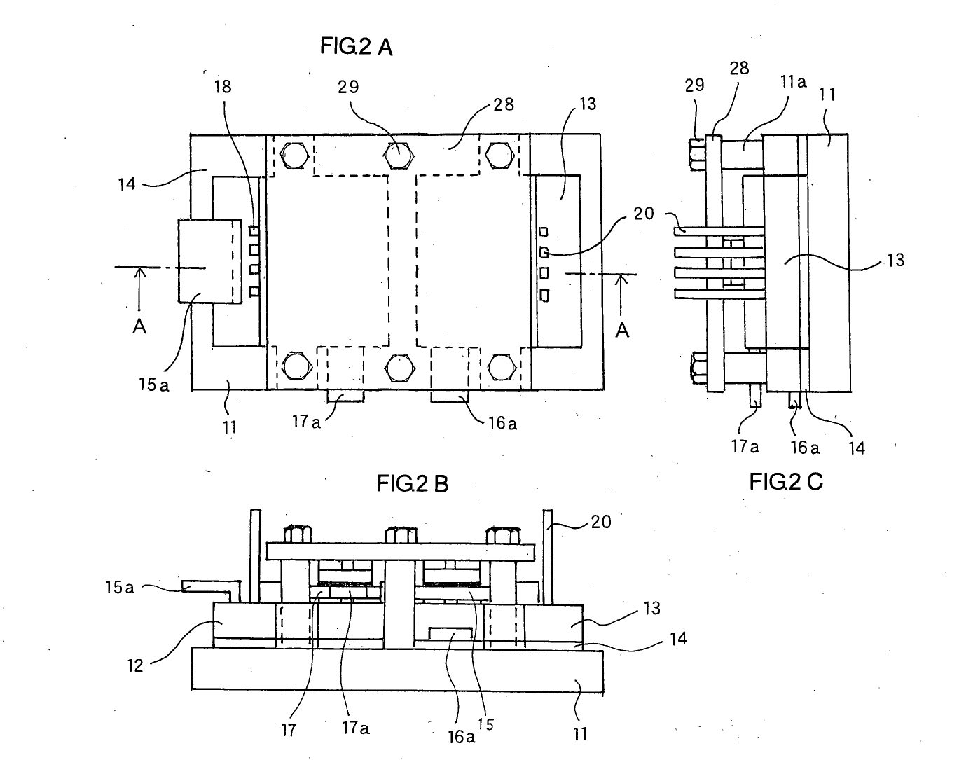

FIG. 2A to FIG. 2C are views showing the external appearance of the semiconductor device fitted to a cooling section 11, where FIG. 2A is a plan view, FIG. 2B is a front view, and FIG. 2C is a side view. The IGBT 2 and the diode D2 shown in FIG. 1 are provided at an unit 12, and the IGBT 1 and the diode D1 are provided at an unit 13. The units 12 and 13 are arranged in parallel or horizontally with respect to each other on the cooling section 11 via an insulating member 14. For example, a composite material of silicon and alumina etc. is used at the insulating member 14 but it is also possible to use various materials such as acrylic materials, epoxy materials, imide materials, or ceramic materials etc. providing that such materials provide the insulation and heat dissipation or heat radiation required for functionality and reliability. For example, a heat dissipating sheet with a silicon base may be used. Further, in the event that the cooling section 11 is formed of an aluminum material, it is possible to omit the insulating member 14 by anodizing the cooling section 11 so as to form an insulating film on the surface of the aluminum material. A plurality of supports 11a are provided at the cooling section 11 and a plate member 28 is fitted to the upper ends of the supports 11a.

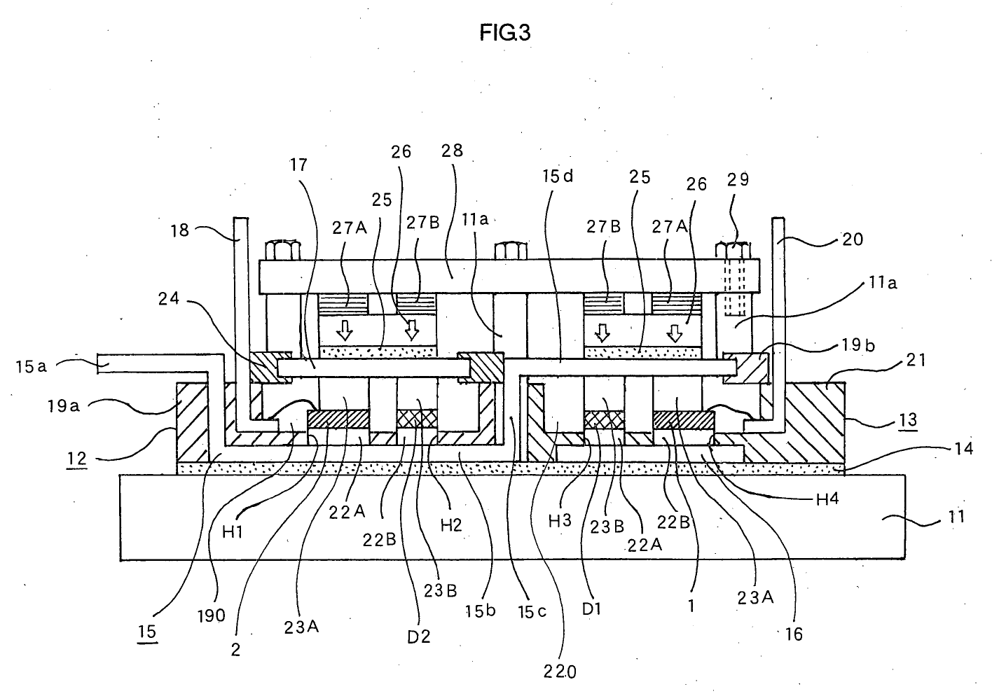

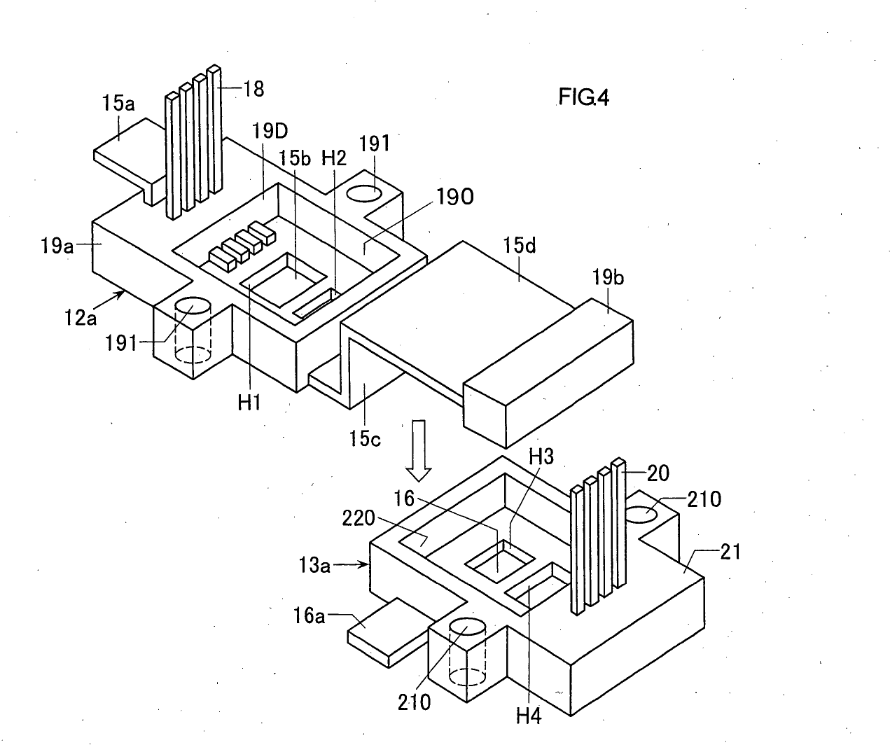

Although not shown in the drawings, a path is formed within the cooling section 11 and the units 12 and 13 are kept cool as a result of coolant flowing within this path. A terminal 15a of an electrode plate 15 provided at unit 12 are led out from the upper surface of the unit 12 and extends to the left side of the apparatus. Terminals 16a and 17a of bus bars 16 and 17 (refer to FIG. 3) are led out in such a manner as to extend to the near side of the front view shown in FIG. 2B.

FIG. 3 is a cross-sectional view along A-A of FIG. 2A. The unit 12 houses the IGBT 2 and the diode D2 within a casing constituted of the electrode plate 15, a gate-terminal 18 and frame sections 19a and 19b. On the other hand, the unit 13 houses the IGBT 1 and the diode D1 within a casing constituted of the bus bar 16, a gate terminal 20 and a frame section 21. The electrode plate 15 is bent over in a stepped shape so as to from a step in a longitudinal direction, and is constituted of a bus bar 15b on which the IGBT 2 and the diode D2 are mounted, a bus bar 15d on which the IGBT 1 and the diode D1 are mounted, the terminal 15a extending to the left side in the drawings of the unit 12, and a connecting section 15c linking the bus bar 15b and the bus bar 15d.

FIG. 4 is a perspective view showing a casing 12a for the unit 12 and a casing 13a for the unit 13. Insulating resin is used at the frame sections 19a, 19b and 21 of the casing 12a and 13a. In this embodiment, the casing 12a is formed by insertion-molding the electrode plate 15 and the gate terminal 18 using resin, and similarly the casing 13a is formed by insertion-molding the bus bar 16 and the gate terminal 20 using resin. The molding is by no means limited to the insertion molding. It is also possible to form the casing 12a and 13a by adhering the bus bars 15 and 16 to frames formed of resin.

The insulating resin used for the frame sections 19a, 19b and 21 is preferably resin material capable of withstanding high-temperature environments and, for example, PPS (polyphenylene sulfide), PBT (polybutylene terephthalate) and PA (polyamide) etc. may be used. Further, the material used in the bus bars 15 to 17 preferably has superior conductivity and heat transfer characteristics and copper, aluminum, or various alloys thereof can be employed.

Through-holes 210 passing vertically through are formed at the frame section 21. The unit 13 is positioned on the cooling section 11 as a result of the supports 11a of the cooling section 11 being inserted through the through-holes 210 while mounting the unit 13 on the cooling section 11. The bus bar 16 provided at the unit 13 is arranged at the bottom surface of the casing 13a and the back surface of the bus bar 16 is exposed opposite to the bottom surface of the casing 13a.

Further, as shown in FIG. 4, a housing space 220 for housing the IGBT 1 and the diode D1 is formed at the frame section 21 and rectangular recesses H3 and H4 are formed within the housing space 220. The front surface of the bus bar 16 is exposed at the bottom surfaces of the recesses H3 and H4. A wire connecting section (refer to FIG. 3) of the gate terminal 20 is exposed within the housing space 220.

When housing the IGBT 1 and the diode D1 within the housing space 220 of the casing 13a, buffer members 22A and 22B are arranged on the bus bar 16 within the recesses H3 and H4, and the IGBT 1 and the diode D1 are then mounted on the buffer members 22A and 22B respectively. The buffer members 22A and 22B are connected to the bus bar 16 using solder, for example. Electrodes for the IGBTs 1 and 2 and the diodes D1 and D2 are formed on both front and back surfaces of the chip with, for example, in the case of the IGBTs 1 and 2, an emitter electrode and gate electrode being formed on the front side and a collector electrode being formed on the reverse side.

The buffer members 22A and 22B electrically connect the bus bar 16 with the rear surface side electrodes of the IGBT and the diode D1 and function to reduce thermal stress due to differences in the linear expansion coefficients between the bus bar 16, and the IGBT 1 and the diode D1. A material with a linear expansion coefficient close to that of the semiconductor chip, i.e., the IGBT 1 and the diode D1, employing a silicon substrate such as, for example, molybdenum or tungsten, or a member that is a combination of molybdenum or tungsten and copper is used as the buffer members 22A and 22B. Of course, it is preferable to use a material with a low volume resistivity in order to keep electrical resistance low.

When the semiconductor chips 1 and D1 make direct contact with the bus bar 16 of a different linear expansion coefficient, there is a fear of friction at the chip surfaces due to expansion and contraction due to changes in temperature. It is therefore possible to prevent this kind of problem by interposing the buffer members 22A and 22B with close linear expansion coefficients between the semiconductor chips 1 and D1 and the bus bar 16. It is possible to omit the buffer members 22A and 22B in the event that the bus bar 16 is thin or that the differences in the linear expansion coefficients of the semiconductor chips 1 and D1 and the bus bar 16 is small.

The gate electrode provided at the front surface of the IGBT 1 is wire-bonded to the wire connecting section of the gate terminal 20 provided at the frame section 21. Buffer members 23A and 23B are mounted on the emitter electrode of the IGBT 1 and the front surface side electrode of the diode D1. The buffer members 23A and 23B are members having the same function as the buffer members 22A and 22B described above, with composite members of molybdenum and copper being employed here. Namely, molybdenum is arranged at the chip side of the buffer members 23A and 23B, and copper is arranged at the upper side (the side of the bus bar 15b described later) of the buffer members 23A and 23B. It is also possible to employ tungsten in place of the molybdenum or to employ a member principally constituted of tungsten or molybdenum.

On the other hand, at the unit 12, the electrode plate 15 is bent into a stepped shape at a substantially central part, and the bus bar 15b on the left side of the connecting section 15c is arranged at the bottom surface of the casing 12a. The connecting section 15c and the right side bus bar 15d are drawn out at the right side of the unit 12 and the bus bar 15d is provided so as to extend above the unit 13 which is provided in parallel with the unit 12. The rear surface of the bus bar 15d of the electrode plate 15 are in contact with the upper surfaces of the buffer members 23A and 23B arranged on the IGBT 1 and the diode D1.

As shown in FIG. 4, a housing space 190 in which the IGBT 2 and the diode D2 are housed is formed at the frame section 19a of the casing 12a and rectangular recesses H1 and H2 are formed within the housing space 190. The front surface side of the bus bar 15b is exposed at the bottom surfaces of the recesses H1 and H2. A wire connecting section of the gate terminal 18 is exposed within the housing space 190. Further, through-holes 191 through which the supports 11a are inserted are formed at the frame section 19a. The unit 12 is positioned on the cooling section 11 by mounting the unit 12 on the cooling section 11 in such a manner that the supports 11a are inserted through the through-holes 191.

As shown in FIG. 3, the buffer members 22A and 22B are arranged within the recesses H1 and H2 formed within the housing space 190 and are connected using solder. The IGBT 2 and the diode D2 are mounted oh the buffer members 22A and 22B respectively. The gate electrode formed at the surface side of the IGBT 2 is wire-bonded with the gate terminal 18 provided at the frame section 19a. The buffer members 23A and 23B are mounted on the emitter electrode of the IGBT 2 and the front surface side electrode of the diode D2. The bus bar 17 is positioned on the buffer members 23A and 23B.

FIG. 5 is a perspective view of the bus bar 17, with an insulating resin frame 24 being integrally formed at each of left and right end sections of the bus bar 17. Further, the terminal 17a (refer to FIG. 2) projecting to the near side of device is formed at the bus bar 17. As shown in FIG. 3, when the frames 24 of the bus bar 17 are mounted on the frame section 19a of the unit 12, the rear surface side of the bus bar 17 comes into contact with the buffer members 23A and 23B mounted on the IGBT 2 and the diode D2.

Auxiliary cooling members 26 are arranged on the bus bar 15d and the bus bar 17 respectively via an insulating member 25. Resilient members 27A and 27B consisting of springs or rubber etc. are arranged on each auxiliary cooling member 26. The same material as the insulating material 14 described above is used for the insulating members 25. The auxiliary cooling members 26 function as thermal mass for moderating rapid rises in temperature of the semiconductor chips 1, 2, D1 and D2 and may be large metal blocks etc. of high heat capacity.

The plate member 28 having sufficient rigidity is arranged on the resilient members 27A and 27B and is fitted to the supports 11a using bolts 29. At this time, the resilient members 27A and 27B are compressed by the plate member 28 and generate a pressing force urging the auxiliary cooling members 26 downwards. As a result, the bus bar 17 and the bus bar 15d are respectively pressed down so as to bring about contact by pressing of the IGBT 2 and the diode D2, the bus bar 17 and the bus bar 15b, and of the IGBT 1 and the diode D1, the bus bar 15d and the bus bar 16.

As described above, the bus bar 17 is erected on the semiconductor chips 2 and D2. Further, the electrode plate 15 is bent around so that the bus bar 15d is erected on the semiconductor chips 1 and D1 so that each of the bus bars 15b, 15d, 16, and 17 make contact through pressing with the semiconductor chips 1, D2, 2 and D2. This means that the installation space for the semiconductor device can be made small and the device itself can be made small.

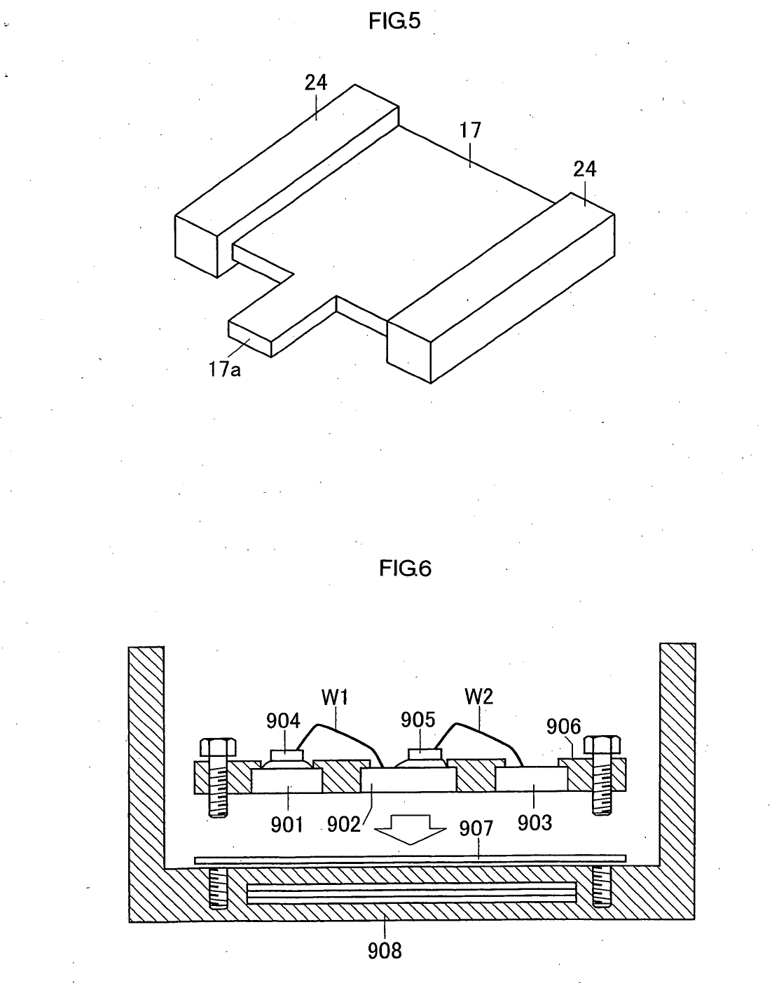

FIG. 6 is a view showing a comparative example of a preferred embodiment where three bus bars 901 to 903 are arranged in parallel, with an IGBT 904 and an IGBT 905 being mounted on the bus bars 901 and 902. The bus bars 901 to 903 are formed integrally using a resin mold, and are fixed to a cooling section 908 via a heat-dissipating sheet 907. An emitter electrode of the IGBT 904 is connected to the bus bar 902 using a bonding wire W1, and an emitter electrode of the IGBT 905 is connected to the bus bar 903 using a bonding wire W2. Namely, the bus bar 901 corresponds to the bus bar 16 described previously, the bus bar 902 corresponds to the bus bar 15b, and the bus bar 903 corresponds to the bus bar 17.

In the case of FIG. 6, the bus bar 903 is arranged in parallel but in this embodiment, the corresponding bus bar 17 is erected above the IGBT 2, and the space in a direction from left to right of the drawings can therefore be made small. Further, the bus bar 15d and the bus bar 17 are pressed independently. The pressing force for the semiconductor chips 1 and D1 and the pressing force for the semiconductor chips 2 and D2 are therefore more dispersed, and it is possible to increase the evenness of the surface pressure occurring at the chip contact surfaces. Further, as bonding wire is not used in making connections, the number of assembly steps can be reduced, and reliability can be improved.

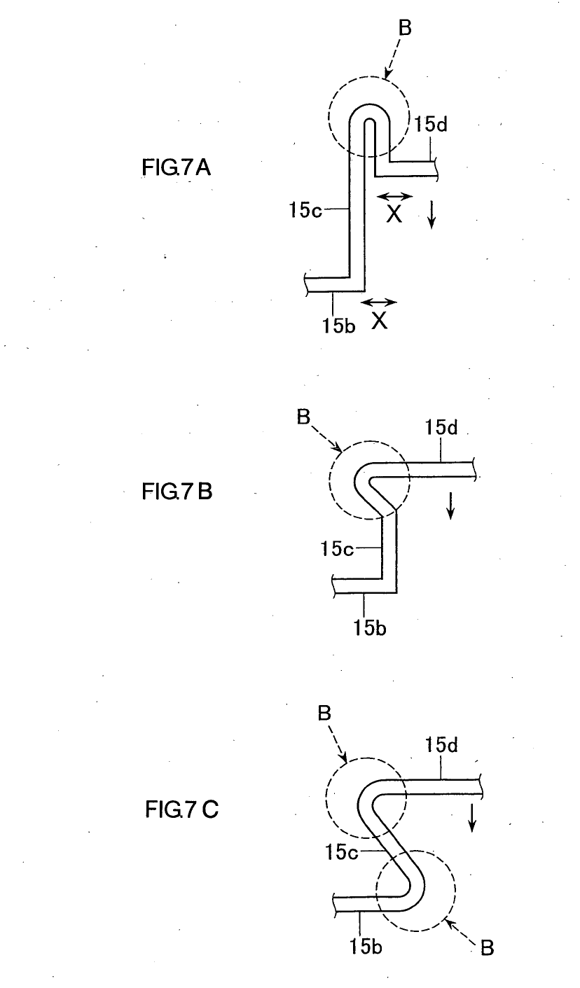

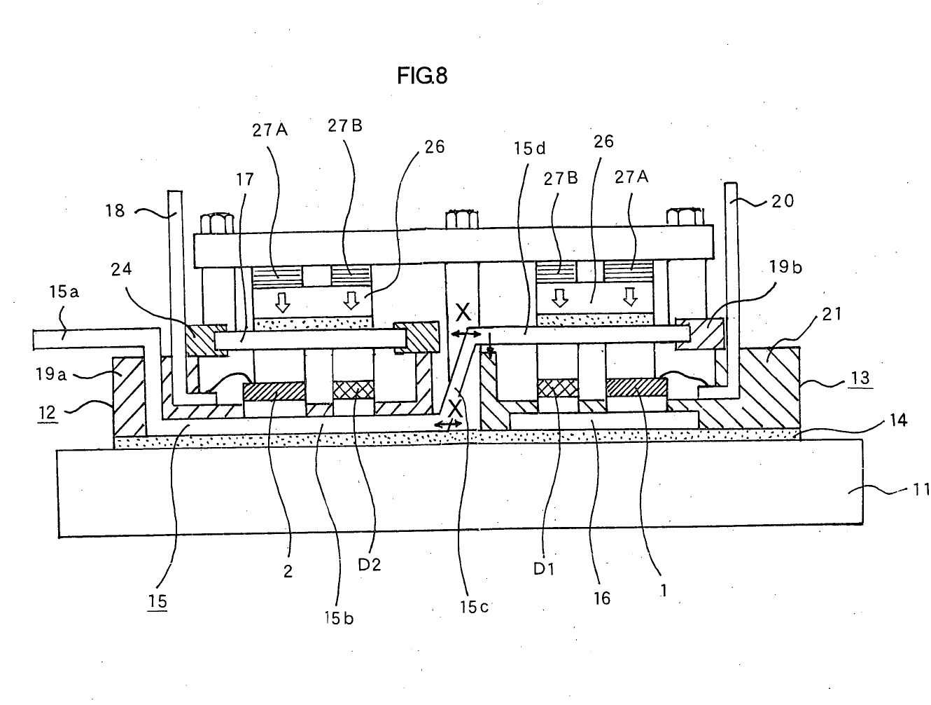

FIG. 7A to FIG. 7C and FIG. 8 show a modified example of the connecting section 15c of the electrode plate 15. As shown in FIG. 7A to FIG. 7C, a bent section B that deforms easily is formed at the connecting section 15c. As a result, when the bus bar 15d is pressed and is displaced downwards in the drawing (refer to FIG. 3), reaction force of the connecting section 15c is reduced, and uniform pressure can be implemented with respect to the chip surfaces of the semiconductor chips 1 and D1.

In FIG. 7A, a bent section B projecting in an upward direction is formed at the connecting section 15c so that the bus bar 15d can be displaced in a vertical direction. In FIG. 7B, a bent section B projecting in a left direction is formed at the connecting section 15c and the bus bar 15d can therefore easily be displaced in a vertical direction. In FIG. 7C, the connecting section 15c is curved in an S-shape to form bent sections B and the bus bar 15d can therefore easily be displaced in a vertical direction. Further, it is also possible to displace the bus bar 15d in a vertical direction by inclining the connecting section 15c as shown in the cross-sectional drawing of FIG. 8, and in this manner, reaction force of the connecting section 15c can be reduced at the time of pressing. Further, a bent section B as shown in FIG. 7A and FIG. 7B may be formed at the inclined connection section 15c. Since the bus bars 15d and 15b are capable of expanding and compressing in the direction of an arrow X in FIG. 7A and FIG. 8 as a result of changes in temperature, the connecting section 15c is preferably formed as shown in FIG. 7A or FIG. 8 so that compression and expansion due to temperature may be absorbed.

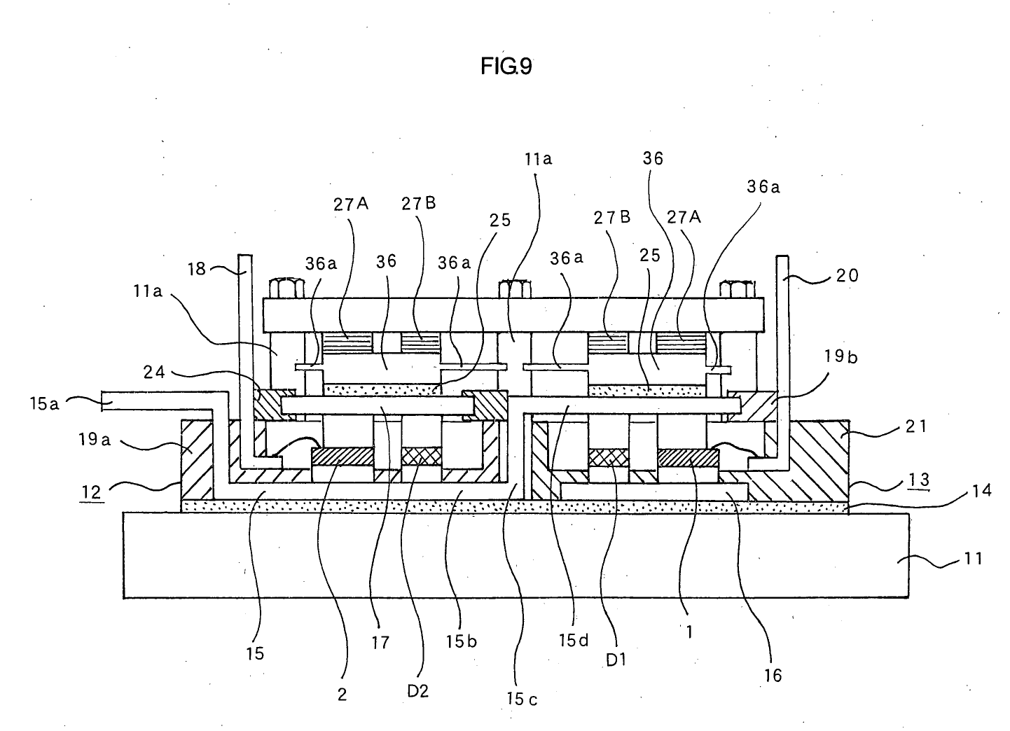

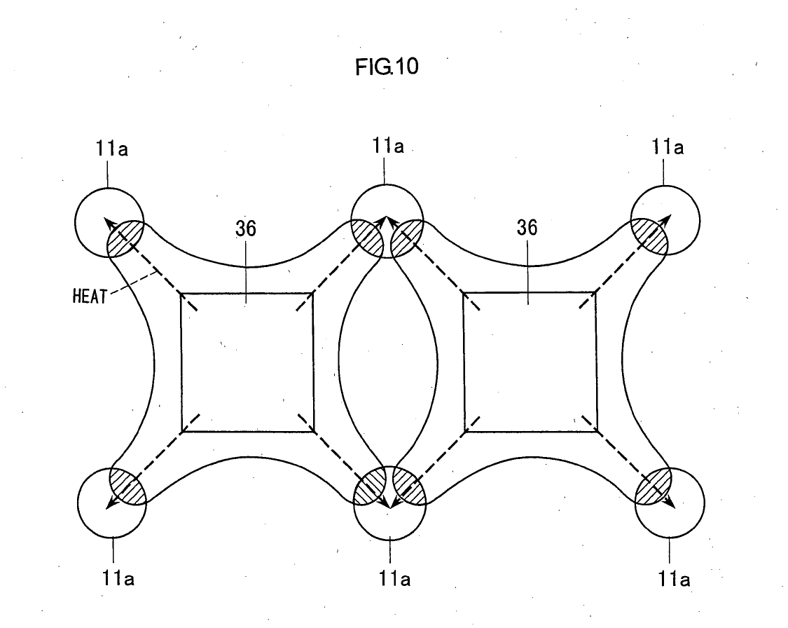

FIG. 9 and FIG. 10 are views showing modified examples of the auxiliary cooling members 26. At auxiliary cooling members 36 shown in FIG. 9, a thin extending section 36a is formed at a side surface, and this extending section 36a comes into contact with the support 11a. FIG. 10 is a plan view of the auxiliary cooling members 36. A slit is formed at the side surface of each support 11a and the thin extending sections 36a extending from the four corners of each of the auxiliary cooling members 36 are inserted through these slits and are adhered using an adhesive with superior heat transfer properties. Heat of the auxiliary cooling members 36 is transmitted via the extending sections 36a to the supports 11a established at the cooling section 11 and is transmitted to the cooling section 11 by the supports 11a. As a result, it is possible to increase heat dissipation effects through the auxiliary cooling members 36. The extending sections 36a are formed so as to be thin and the generation of reaction force at the time of pressing can therefore be suppressed.

### Second Embodiment

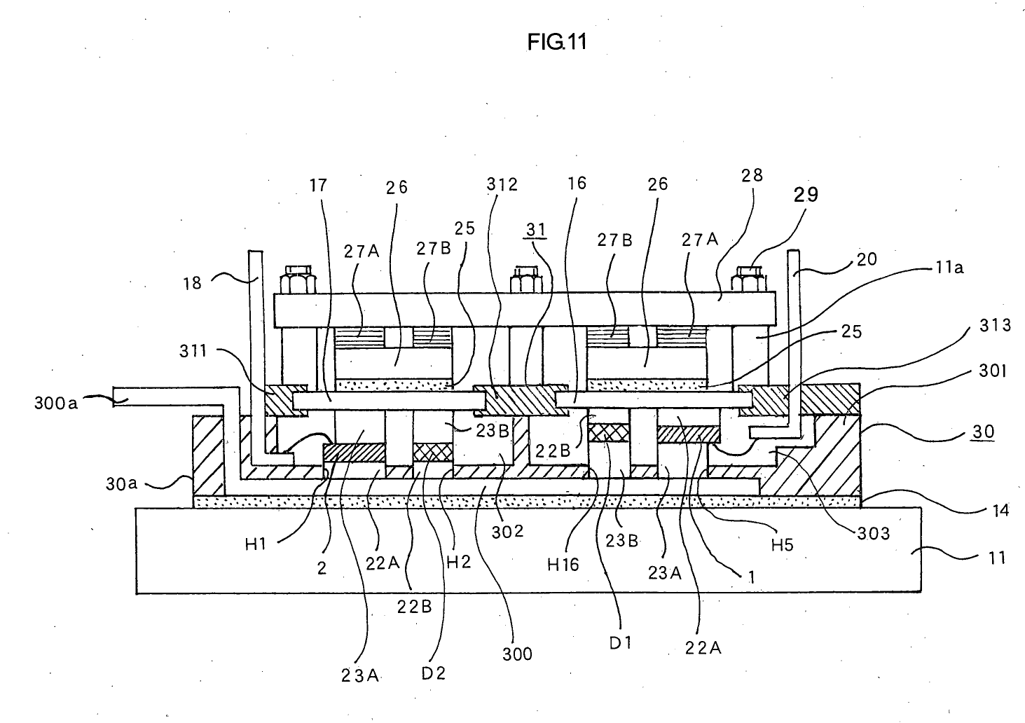

FIG. 11 is a cross-sectional view of a second embodiment of a semiconductor device of the present invention. Compared to the apparatus shown in FIG. 3, units 30 and 31 at which bus bars are provided are different, but other aspects of the configuration are substantially the same as those shown in FIG. 3. The following is a description centered on the units 30 and 31. The unit 30 is mounted on the cooling section 11 via the insulating member 14 and is constituted of a bus bar 300, the IGBT 1, the IGBT 2, the diode D1 and the diode D2 mounted on the bus bar 300, and the gate terminals 18 and 20.

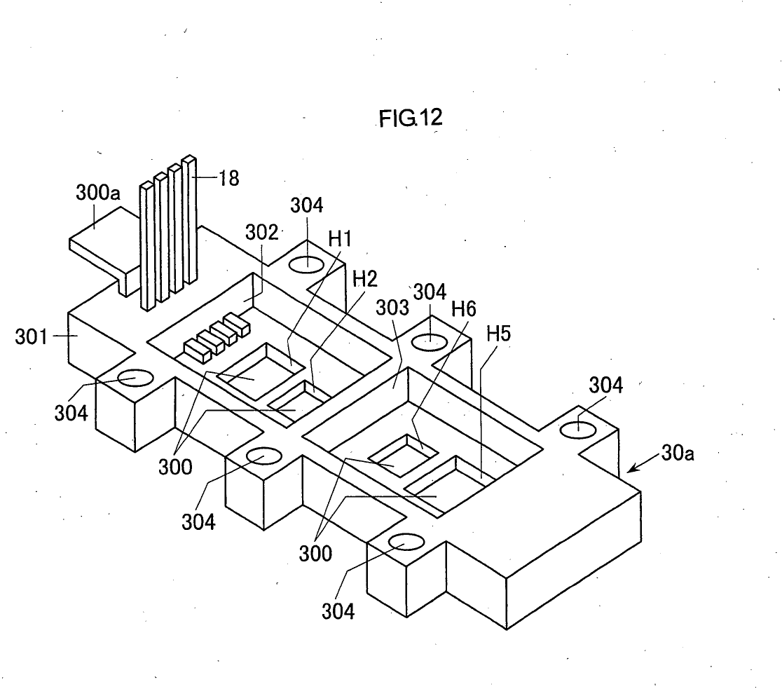

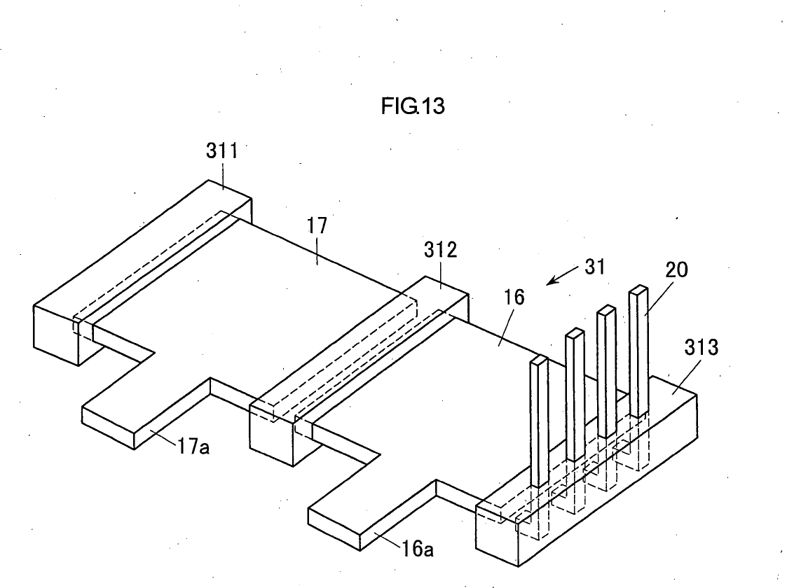

FIG. 12 is a perspective view showing a casing 30a of the unit 30. The casing 30a is formed integrally by forming a frame section 301 by insertion molding the bus bars 300 and the gate terminal 18 using insulating resin. As shown in FIG. 11, the rear surface of the bus bar 300 is exposed opposite to the rear surface of the casing 30a, and a terminal 300a of the bus bar 300 extends towards the side along a longitudinal direction of the casing 300a, i.e., to the left in the drawing. At the frame section 301, a housing space 302 for holding the IGBT 2 and the diode D2 and a housing space 303 for holding the IGBT 1 and the diode D1 are formed along the longitudinal direction of the frame section 301. Further, six through-holes 304 through which the supports 11a are inserted are formed at the frame section 301.

The gate terminal 18 is molded close to the housing space 302 and a wire connection section is exposed within the housing space 302. The rectangular recesses H1 and H2 are formed within the housing space 302 and rectangular recesses H5 and H6 are formed at the housing space 303. The front surface side of the bus bar 300 is exposed at the bottom surfaces of the recesses H1, H2, H5 and H6.

FIG. 13 is a perspective view showing the unit 31. The unit 31 is configured in such a manner that the bus bars 16 and 17 are arranged in parallel, and the gate terminal 20 is arranged in the vicinity of the bus bar 16 and is insert molded using insulating resin so as to form frames 311, 312 and 313 in an integral manner. Ends neighboring the bus bars 16 and 17 are coupled by the resin frame 312. The frames 311 and 313 are formed at the other ends of the bus bars 16 and 17. Further, a lower end of gate terminal 20 projects lower down than the bus bar 16, and in the case where the unit 31 is combined with the casing 30a, the projecting end is arranged so as to be exposed within the housing space 303 of the casing 30a.

As shown in FIG. 11, the casing 30a is mounted on the cooling section 11 via the insulating member 14. The buffer members 22A and 22B are arranged within the recesses H1 and H2 formed within the housing space 302, and the IGBT 2 and the diode D2 are mounted on each of the buffer members 22A and 22B. The gate electrode formed at the front surface side of the IGBT 2 is wire-bonded with the gate terminal 18. The buffer members 23A and 23B are mounted on the emitter electrode of the IGBT 2 and the front surface side electrode of the diode D2.

The buffer members 23B and 23A are arranged within the recesses H5 and H6 formed within the housing space 303. The IGBT 1 is then mounted on the buffer member 23A arranged within the recess H5 with the front surface side on which the emitter electrode is formed facing downwards. The gate electrode of the IGBT 1 is wire-bonded to the gate terminal 20. On the other hand, the diode D1 is mounted on the buffer member 23B arranged within the recess H6 with the surface on which the surface-side electrode is formed facing downwards. The buffer members 22A and 22B are provided respectively between the IGBT 1 and the diode D1, and the bus bar 16. In this embodiment, after the casing 30a and the unit 31 are combined, the housing space 303 is sealed and wire bonding the gate terminal 20 and the gate electrode of the IGBT 1 therefore becomes difficult. It is therefore preferable to fix at least the buffer member 22A, the IGBT 1 and the gate terminal 20 to the unit 31.

Next, the unit 31 is mounted on the unit 30 in such a manner that the bus bar 17 is arranged on the buffer members 23A and 23B of the housing space 302 and the bus bar 16 is arranged on the buffer members 22A and 22b of the housing space 303. The insulating material 25, the auxiliary cooling member 26 and the resilient members 27A and 27B are mounted in order on each of the bus bars 16 and 17.

The plate member 28 is arranged on the resilient members 27A and 27B and is fitted to the supports 11a using the bolts 29. When the plate member 28 is fitted and the bolts 29 are fastened, the resilient members 27A and 27B are compressed and the bus bar 17 and the bus bar 16 are respectively pressed downwards. As a result, it is possible to bring about pressing contact between the IGBT 2 and the diode D2, and the bus bar 17 and the bus bar 300, and between the IGBT 1 and the diode D1, and the bus bar 16 and the bus bar 300.

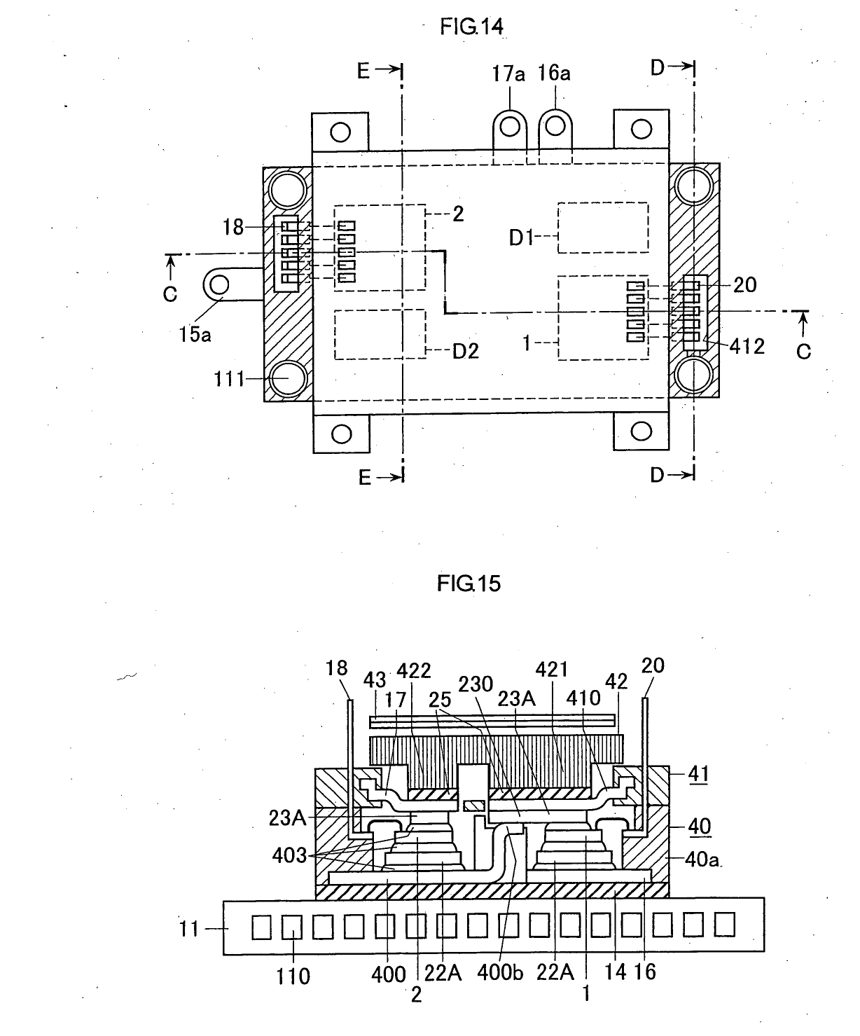

In the second embodiment described above, a configuration is adopted where the IGBT 1 and the diode D1 are arranged upside down on the bus bar 300 and the bus bar 16 is arranged on the IGBT 1 and the diode D1. In this embodiment, the electrode plate 15 shown in FIG. 3 is replaced with the bus bar 300, the IGBT 1 and the diode D1 are arranged upside down, and the bus bar 300 corresponding to the bus bar 15d is arranged below the bus bar 16. Since the bus bars 16 and 17 are erected on the semiconductor chips 1, 2, D1, D2, it is possible to make the device small as with the first embodiment. Further, the terminals 16a and 17a connected to the P-side and N-side of a power supply are arranged in close proximity as shown in FIG. 14 and it is therefore possible to reduce inductance between these lines. Further, the arrangement of the bus bar with an external device and the connection between the bus bars are straightforward because the terminals 16a and 17a are on the same side surface.

Moreover, since there is no connecting section 15c as shown in FIG. 3 at the bus bar 300, the reaction force does not occur at the connecting section 15c when pressure is applied. Therefore, uniformity of pressing on the contact surfaces of the chips can be improved. It is also possible to form a bent section at a central section of the bus bar 300 so as to achieve separation of the pressing force to the left and right.

### Third Embodiment

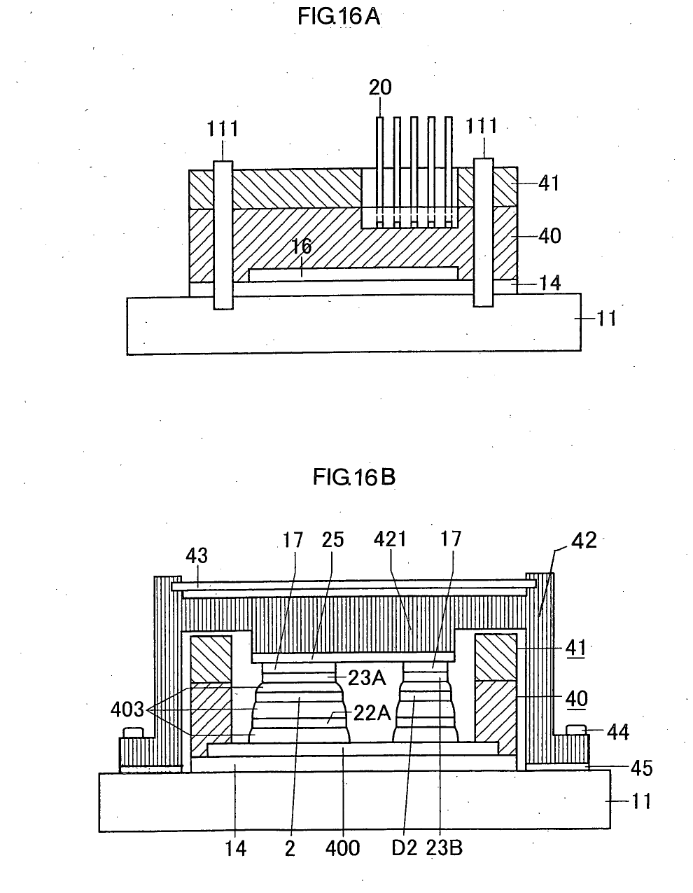

FIG. 14 to FIG. 17 are views of a third embodiment of a semiconductor device of the present invention. FIG. 14 is a plan view of the semiconductor device, and FIG. 15 is a cross-sectional view along C-C of FIG. 14. Further, FIG. 16A is a cross-sectional view along D-D of FIG. 14 and FIG. 16B is a cross-sectional view along E-E. As shown in FIG. 14, the IGBT 1, the IGBT 2, the diode D1 and the diode D2 are provided with the device as with the first and second embodiments.

In the first and second embodiments described above, the semiconductor chips 1, 2, D1 and D2 are arranged along a longitudinal direction of the device (direction from left to right in the drawings). However, in the third embodiment, a pair of the IGBT 1 and the diode D1 and a pair of the IGBT 2 and the diode D2 are each arranged perpendicular to a longitudinal direction, i.e., along a vertical direction in the drawing. Portions that are the same as for the first and second embodiments are given the same numerals.

As shown in FIG. 15, the semiconductor device is mounted on the cooling section 11 via the insulating member 14. As described above, a path 110 is formed at the cooling section 11 and coolant is supplied to within the path 110. The semiconductor device is constituted of a bottom unit 40, a middle unit 41 and a top unit 42 laid one on top of another, with the IGBT 1 the IGBT 2, the diode D1 and the diode D2 being housed within a casing 40a of the unit 40. As shown in FIG. 16A showing the cross-sectional view along D-D, four positioning pins 111 are erected on the cooling section 11 so as to provide positioning when the units 40 and 41 are laid one on top of the other.

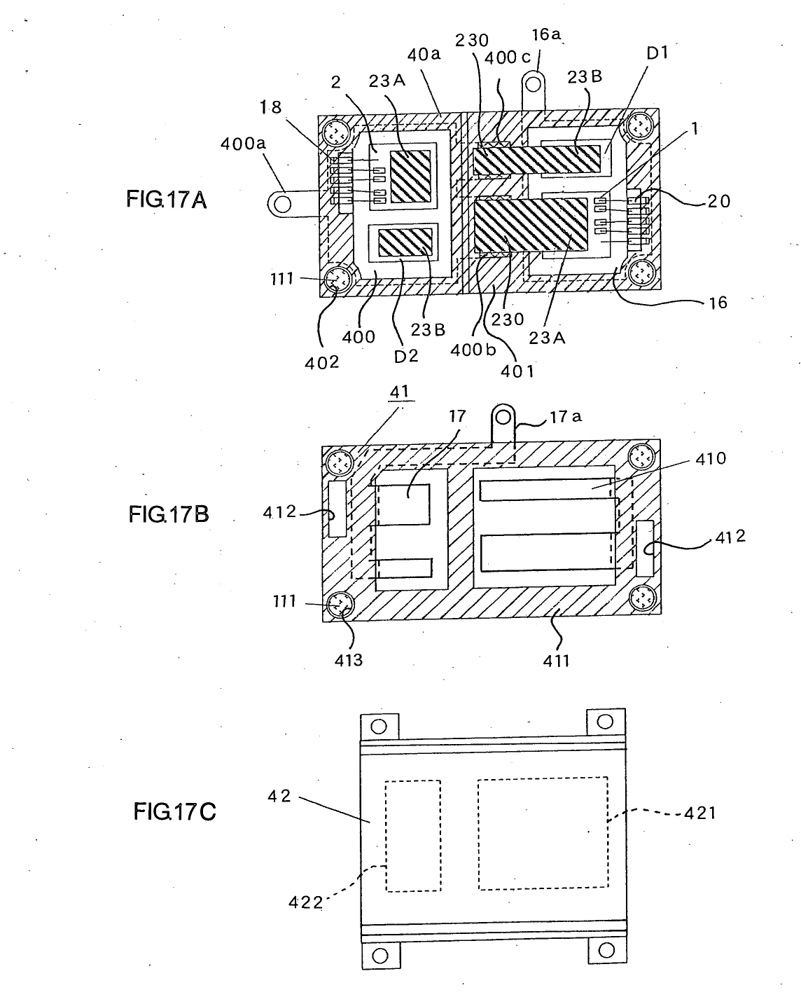

FIG. 17A, FIG. 17B and FIG. 17C are plan views of the units 40, 41 and 42 respectively. As shown in FIG. 17A, the casing 40a is formed integrally by forming a frame section 401 by insertion molding the bus bars 16 and 400 using insulating resin. The bus bars 16 and 400 constitute part of the bottom section of the casing 40a and the bottom surfaces of the bus bars 16 and 400 are exposed opposite to the rear surface of the casing 40a.

Further, the bus bar 400 is bent in a vertical direction, i.e., perpendicular to the drawing sheet, at a substantially central portion of the casing 40a, and horizontal sections 400c and 400b formed at an upper end section are exposed at an upper surface of the frame section 401. The terminal 16a of the bus bar 16 is taken out from a side surface of the upper side in the drawing, and a terminal 400a of the bus bar 400 is taken from a side surface of the left side of the drawing. Through-holes 402 through which the positioning pins 111 are inserted are formed at the four corners of the frame section 401.

The unit 41 is integrally formed by forming a frame section 411 by insertion-molding the bus bar 17 and a bus bar 410 using insulating resin, as shown in FIG. 17B. The terminal 17a of the bus bar 17 is taken out from the side surface of the frame section 411. Rectangular holes 412 through which the gate terminals 18 and 20 (refer to FIG. 15) are passed are formed in the frame section 411. Further, through-holes 413 through which the positioning pins 111 are inserted are formed at the four corners of the frame section 411.

The unit 42 is a member having a function for pressing the bus bars 17 and 410 and a heat dissipating function for dissipating the heat of the semiconductor chips 1, 2, D1 and D2 to the cooling section 11 with its cross-section, being a shape of a gate, as shown in FIG. 16B of the cross-sectional view along E-E. Projections 421 and 422 for pressing are formed at the rear surface of the unit 42. A control plate 43 (refer to FIG. 16B) is fixed to the upper surface of the unit 42.

Returning to FIG. 15, the IGBT 1 and the diode D1 are mounted on the bus bar 16 of the casing 40a. Each of the semiconductor chips 1 and D1 is fixed by soldering by sequentially putting the items on top of one another in the order of a solder 403, the buffer member 22A or 22B, a solder 403, the semiconductor chip 1 or D1, a solder 403 and the buffer member 23A or 23B, then melting the solders 403 in a high-temperature furnace. The buffer members 23A and 23B soldered to the upper parts of the IGBT 1 and the diode D1 respectively are arranged in such a manner as to span the upper surfaces of the IGBT land the diode D1 and the top of horizontal sections 400b and 400c of the bus bar 400 described above (refer to FIG. 17A). As a result, the bus bar 400, the emitter electrode of the IGBT 1 and the surface side electrode of the diode D1 are connected.

Similarly, the IGBT 2, the diode D2, the buffer members 22A, 22B, 23A, 23B and the solders 403 are laid one on top of another on the bus bar 400 and are attached by soldering. The gate electrode of the IGBT 1 is connected by wire bonding to the gate terminal 20, and the gate electrode of IGBT 2 is connected using wire bonding to the gate terminal 18.

Next, the unit 41 shown in FIG. 17B is laid on top of the unit 40. As a result, the bus bar 410 is mounted on the buffer members 23A and 23B on the IGBT 1 and the diode D1, and the bus bar 17 is mounted the buffer members 23A and 23B on the IGBT 2 and the diode D2. The unit 42 is overlaid on the unit 41 and is fastened to the cooling section 11 using bolts 44 (refer to FIG. 16B). During this time, the insulating materials 25 are interposed between the bus bars 17 and 410, and the projections 421 and 422, and a heat-dissipating sheet 45 is interposed between the unit 42 and the cooling section 11.

The unit 42 is fastened to the cooling section 11 using the bolts, and the bus bars 17 and 410 are pressed in the direction to the chips. As a result, the buffer members 23A and 23B on the IGBT 2 and the diode D2 and the bus bar 17 are press-contacted with each other. The buffer members 23A and 23B on the IGBT 1 and diode D1 and the bus bar 410 are also press-contacted with each other. Further, since parts 230 of the buffer members 23A and 23B are sandwiched between the bus bar 410 and the horizontal sections 400b and 400c of the bus bar 400, the parts 230 of the buffer members 23A and 23B, and the horizontal sections 400b and 400c are made into contact with each other through pressure.

Further, it is also possible to have coolant flow within the unit 42 in order to increase thermal dissipation. In the example described above, the buffer members 23A and 23B and the IGBTs 1 and 2, and the diodes D1 and D2 are connected using solder but may also be connected by pressure-welding without using solder.

In the third embodiment also, the bus bars 410 and 17 are erected on the semiconductor chips 1, 2, D1, D2. It is therefore possible to make the device small as with the first embodiment. Further, because the IGBT 1 and the IGBT 2 are attached using solder on the bus bars 16 and 400, wire bonding to the gate terminals is straightforward, and assembly can be made easier. Further, an unbalanced load applied to the semiconductor chips 1, 2, D1, D2 can be alleviated because the solder is plastically deformed at the time of pressing.

### Fourth Embodiment

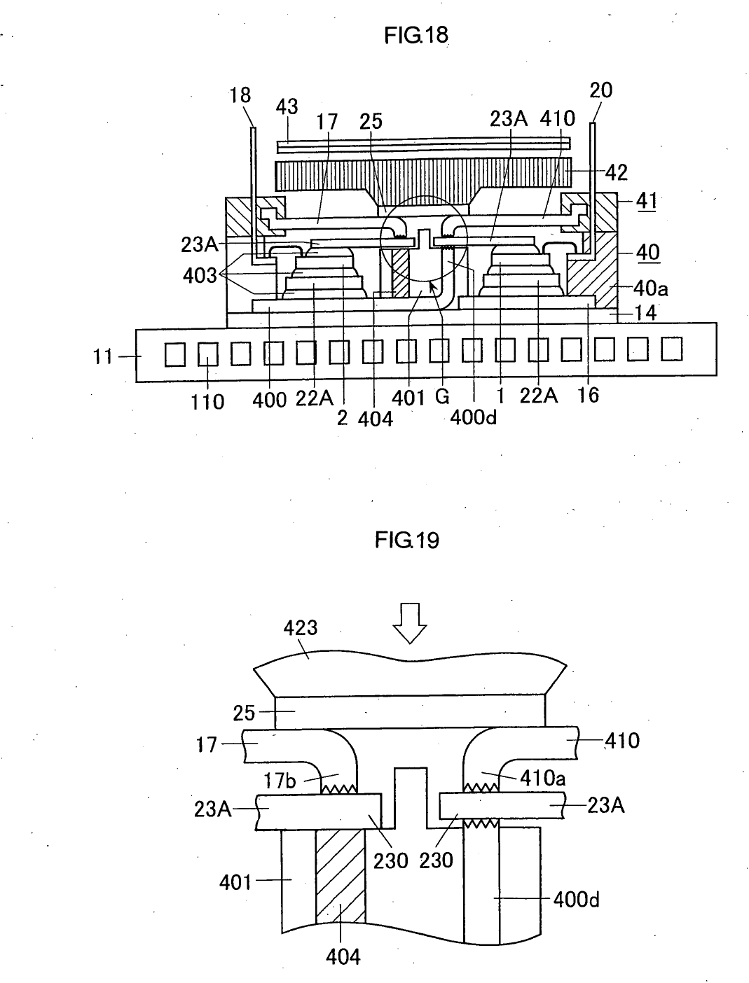

FIG. 18 to FIG. 20 are views showing a fourth embodiment of a semiconductor device of the present invention, where FIG. 18 is a cross-sectional view corresponding to FIG. 15 of the third embodiment, and FIG. 19 is an enlarged view of section G of FIG. 18. As shown in FIG. 18, in this embodiment the semiconductor device is also constituted of the three units 40, 41 and 42 laid one on top of another, but the shape of the bus bars 17 and 410, the buffer members 23A and 23 and the bus bar 400 is different to the third embodiment.

In this embodiment, not only the buffer members 23A and 23B of the semiconductor chips 1 and D1 but also the buffer members 23A and 23B of the semiconductor chips 2 and D2 span across the top of the semiconductor chips 1, 2 D1 and D2 and the frame section 401, and the parts 230 of the buffer members 23A and 23B are mounted on the frame section 401 and a vertical section 400d of the bus bar 400. Further, the ends of the bus bars 17 and 410 are bent downwards so as to form bent sections 17b and 410a, and the bent sections 17b and 410a are mounted on the parts 230 of the buffer members 23A and 23B. The bent sections 17b and 410a and the buffer members 23A and 23B make contact through pressing. A projection 423 making contact with the bent sections 17b and 410a is formed at the center of the rear surface side of the unit 42 and when the unit 42 is fastened to the cooling section 11 using the bolts, the bent sections 17b and 410a are pressed down by the projection 423.

In this manner, the bent sections 17b of the bus bar 17 are press-connected with the parts 230 of the buffer members 23A and 23B, and the bent sections 410a of the bus bar 410 are press-connected with the vertical section 400d of the bus bar 400 by making contact with the parts 230 of the buffer member 23A and 23B through pressing. It is to be noted that while not shown in the drawings, the buffer members 23B and the bus bars 17 and 410 are also designed in a similar manner as the buffer members 23A and the bus bars 17 and 410.

The insulating member 25 is arranged between the projection 423 and the bent sections 17b and 410a. Further, a reinforcing member 404 for preventing plastic deformation of the resin at the time of pressing is provided at the frame section 401 below the press-contacting section. Minute disparities are formed at the contact surfaces at the end of the bent sections 17b and 410a and the vertical section 400d. At the time of press-contact, the disparity portions are plastically deformed so as to absorb variations in inclination and height of the buffer members 23. It is also possible for the surfaces of the buffer members 23A and 23B to be given irregular shapes rather than the bent sections 17b and 410a and the vertical section 400d being given irregular shapes.

In the fourth embodiment, contact just above the semiconductor chips 1, 2, D1 and D2 is avoided and instead contact is made at the frame section 401. The load applied to the semiconductor chips 1, 2, D1 and D2 is therefore small. As a result, it is possible to prevent the occurrence of failure of the semiconductor chips due to the load at the time of pressing. Further, the disparities are formed at the ends of the bent sections 17b and 410a and the vertical section 400d. The disparity portions plastically deforms at the time of pressing, which makes it possible to provide a better contact and to realize a more uniform application of pressure.

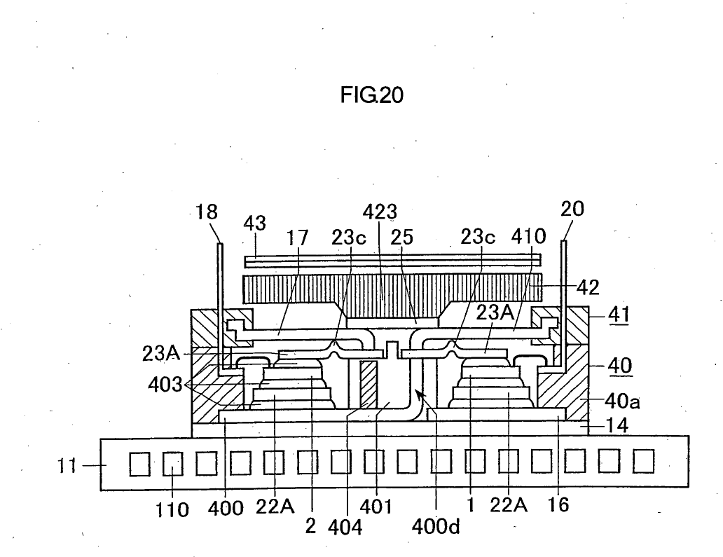

As shown in FIG. 20, bent sections 23c may be formed at the buffer members 23A and, 23B so that the buffer members 23A and 23B can be deformed easily at this portions. Even if the buffer members 23A and 23B are inclined at the time of applying solder, the bent sections 23c are deformed at the time of press-contact so as to alleviate the generation of stress of portions where solder is applied. Reliability of soldered portions can therefore be improved.

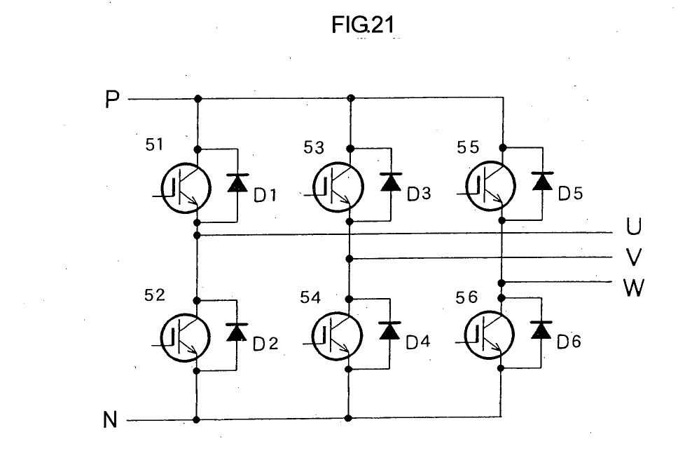

The semiconductor device shown in FIG. 18 corresponds to the single phase inverter circuit shown in FIG. 1 but it is also possible to utilize this configuration in a three-phase inverter circuit shown in FIG. 21 by combining three sets of the configuration of FIG. 18. In FIG. 21, an IGBT 51, an IGBT 52, a diode D1 and a diode D2 are elements constructing a U-phase, an IGBT 53, an IGBT 54, a diode D3 and a diode D4 constitute a V-phase, and an IGBT 55, an IGBT 56, a diode D5 and a diode D6 constitute a W-phase.

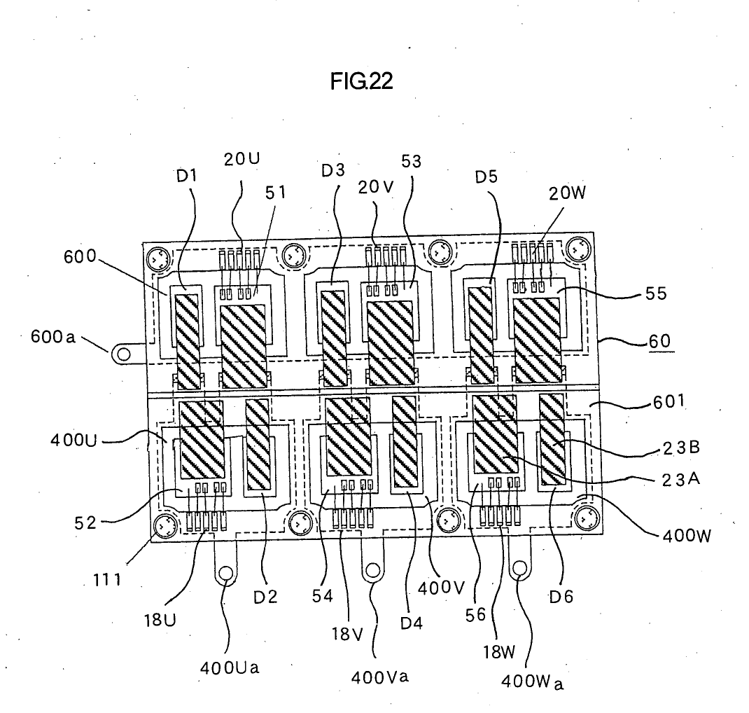

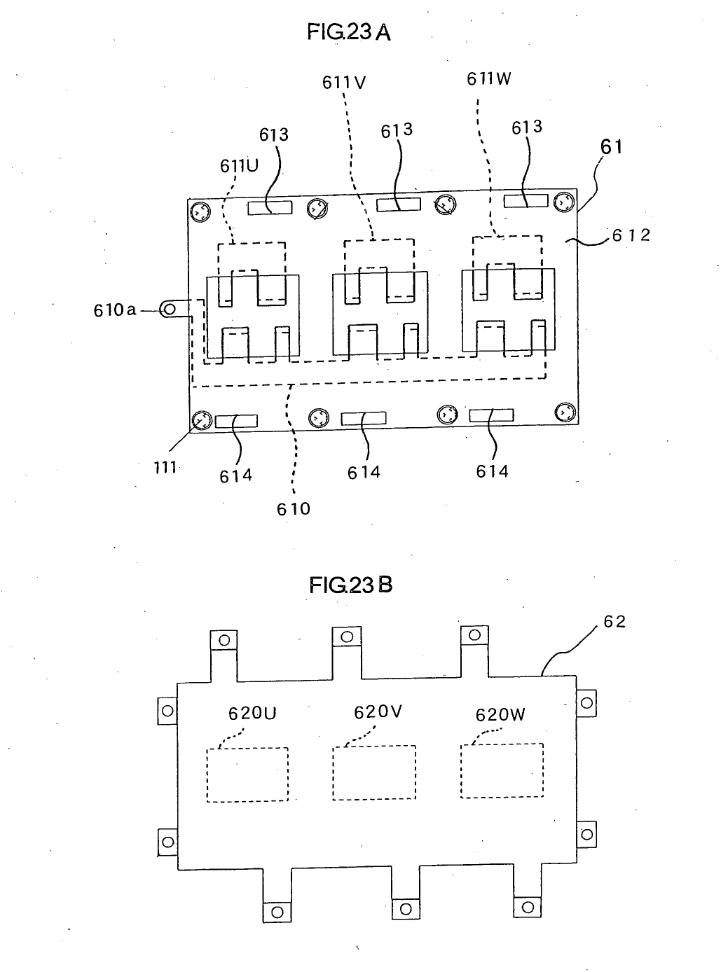

FIG. 22 is a plan view showing a unit 60 corresponding to the unit 40 described above, FIG. 23A is a plan view of a unit 61 corresponding to the unit 41, and FIG. 23B is a plan view of unit 62 corresponding to the unit 42. As shown in FIG. 22, in the unit 60, a bus bar 600 having a terminal 600a connecting to a P-side of the power supply, and bus bars 400U, 400V and 400W having a U-phase output terminal, a V-phase output terminal and a W-phase output terminal respectively are insertion-molded in a frame 601.

The bus bar 600 is formed by integrating the bus bar 16 of the unit 40 for the U, V and W phases and is mounted with the IGBTs 51, 53 and 55 and the diodes D1, D3 and D5. Each of the bus bars 400U, 400V and 400W is the same as the bus bar 400 of the unit 40. Terminals 400Ua, 400Va and 400Wa for each of the bus bars 400U, 400V and 400W are taken from the same side surface of the unit 60. The IGBT 52 and the diode D2 are mounted on the bus bar 400U, the IGBT 54 and the diode D4 are mounted on the bus bar 400V, and the IGBT 56 and the diode D6 are mounted on the bus bar 400W. Further, gate terminals 18U, 18V and 18W each corresponding to the gate terminal 18 of the unit 40 are provided for each of the U, V, and W phases, and the gate terminals 20U, 20V and 20W each corresponding to the gate terminal 20 are for each of the U, V and W phases.

In the unit 61 shown in FIG. 23A, a bus bar 610 and bus bars 611U, 611V and 611W are insertion-molded into a frame section 612. The bus bar 610 is formed by integrating the bus bar 17 of the unit 41 for U, V and W phases, and is provided with a terminal 610a for connecting to the N-side of the power supply. Each of the bus bars 61IU, 611V and 611W is the same as the bus bar 410 of the unit 41. Through-holes 613 through which the gate terminals 20U, 20V and 20W pass and through-holes 614 through which the gate terminals 18U, 18V and 18W pass are formed in the frame 612. Projections 620U, 620V and 620W for applying pressure every U, V and W phase are formed at the rear surface side of the unit 62 shown in FIG. 23B.

In this way, because the bus bars 600 and 610 are integrated for the U, V and W phases, an external connection between terminals for each phase is not necessary as in the case where the semiconductor device shown in FIG. 18 is provided for each phase. It is therefore possible to make the overall device small, and it is also possible to reduce inductance.

### Fifth Embodiment

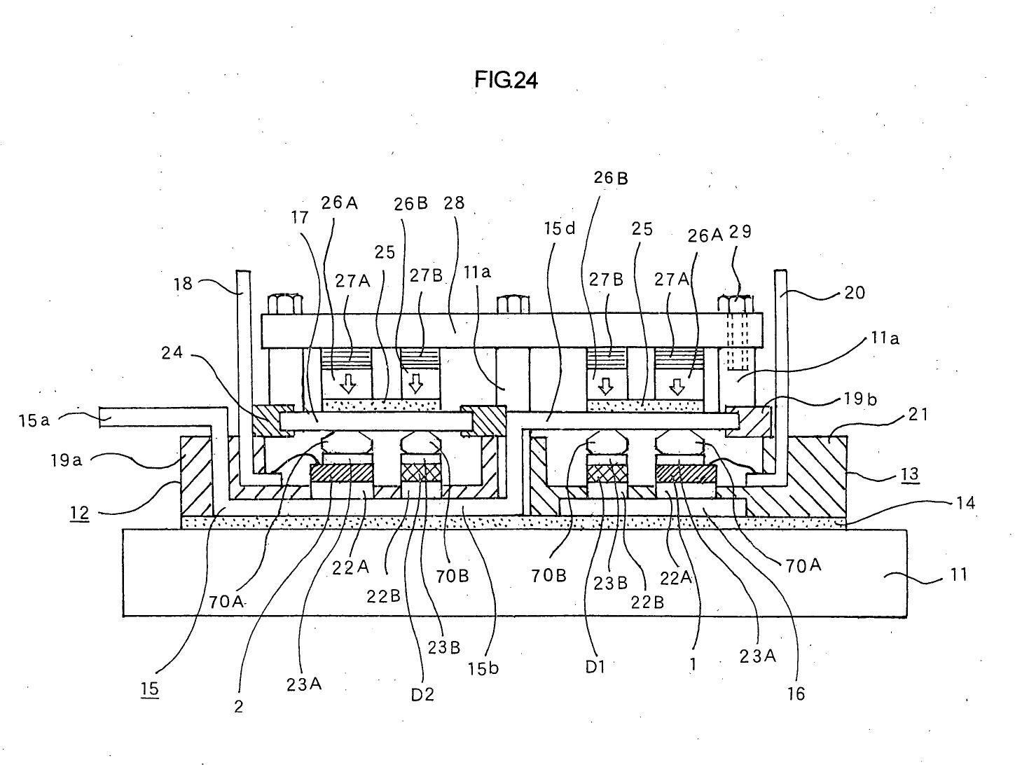

FIG. 24 is a cross-sectional view showing a fifth embodiment. The same numerals are assigned to portions that are the same as for the device shown in FIG. 3. This embodiment ensures that pressure is applied to the semiconductor chip surfaces in a uniform manner while pressing the semiconductor chips onto the bus bars. The following configuration is different from the device shown in FIG. 3.

Firstly, the auxiliary cooling members 26 are provided independently for use with the IGBT chips 1 and 2 and for use with the diodes D1 and D2 so as to give auxiliary cooling members 26A and auxiliary cooling members 26B, respectively.

Secondly, while only the buffer members 23A and 23B are mounted on the semiconductor chips in the device shown in FIG. 3, additional buffer members 70A and 70B having Young's modulus different from that of the buffer members 23A and 23B are arranged on the buffer members 23A and 23B. Namely, in this embodiment, there are provided two buffer members of different Young's modulus. The buffer members 70A and 70B provided on the buffer member 23A and 23B are made of a material with a lower Young's modulus than the buffer members 23A and 23B. For example, in the event that tungsten is used at the buffer members 23A and 23B, copper, aluminum, or an alloy consisting mainly of copper or aluminum, of a Young's modulus that is lower than that of tungsten, is used for the buffer members 70A and 70B.

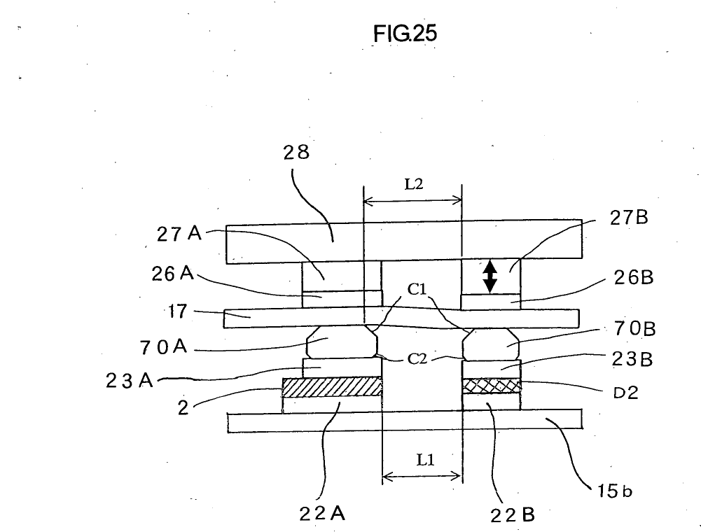

Thirdly, top and bottom edges of the buffer members 70A and 70B of a material of a low Young's modulus are chamfered so that an upper contact surface area S1 of the buffer members 70A and 70B is smaller than a lower contact surface area S2 with the upper contact surface area S1 being contact with the bus bar 17 or 15d and the lower contact surface area S2 being in contact with the buffer member 23A or 23B. In this event, an upper side chamfering dimension C1 is made larger than a lower side chamfering dimension C2 (refer to FIG. 25).

FIG. 25 is a view illustrating the operation of the auxiliary cooling member 26A and the auxiliary cooling member 26B and shows only the side including the semiconductor chips 2 and D2. The IGBT 2 and the diode D2 are mounted next to each other on the bus bar 15b. At this time, there are cases where the heights to the upper surface of the buffer members 70A and 70B may be different due to variations in the thickness of the laminated members or variations in thickness of the solder in the case of application using solder as shown in FIG. 15. In the example shown in FIG. 25, the IGBT chip 2 side is higher than the diode D2 side.

With the device shown in FIG. 3 described above, the auxiliary cooling member 26 is urged downwards by the resilient members 27A and 27B provided independently for each IGBT chip 2 and diode D2. The height of the bus bar 17 can therefore be deformed to adjust to the lower height in the event of a difference in height. As a result, a pressing operation also acts on the semiconductor chip of a lower height.

However, with the device shown in FIG. 3, the auxiliary cooling member 26 is arranged so as to span both the IGBT chip 2 and the diode D2. Therefore, contact with respect to the buffer member 23A or 23B of a lower height may be insufficient and gaps may occur. However, in this embodiment, the auxiliary cooling member 26A on the side of the IGBT chip 2 and the auxiliary cooling member 26B on the side of the diode D2 are provided independently. The bus bar 17 on the side of the diode D2 is therefore deformed downwards by urging force due to the resilient members and 27B as shown in FIG. 25, the contact state of the bus bar 17 and buffer member 70B is good, and pressure is applied in a uniform manner.

Further, the buffer members 70A and 70B are formed of members with a low Young's modulus that are easily deformed and differences in height can therefore be absorbed by deformation of the buffer member 70A that is higher. As a result, deformation of the bus bar 17 becomes smaller and irregularity of pressure application can be suppressed. Since the buffer members 23A and 23B of a higher Young's modulus than the buffer members 70A and 70B are arranged between the buffer members 70A and 70B and the semiconductor chips, even if there is uneven application of pressure from the buffer members 70A and 70B, this is lowered by the buffer members 23A and 23B.

It is possible for deformation to take place more easily by making an interval L2 where deformation of the bus bar 17 takes place larger by making the chamfering dimension Cl for the upper side of the buffer members 70A and 70B large. Further, by making the chamfering dimension C1 large, it is possible to make the distance between the IGBT 2 and the diode D2 smaller while maintaining the interval L2 and the device itself can therefore also be made smaller.

Further, dimensions are set in such a manner that C1>C2, and by making the contact surface areas S1 on the upper side of the buffer members 70A and 70B smaller than the lower side contact surface areas S2, application of pressure from the lower side buffer members 23A and 23B to the semiconductor chips 2 and D2 can be made uniform and unbalanced loads can be suppressed.

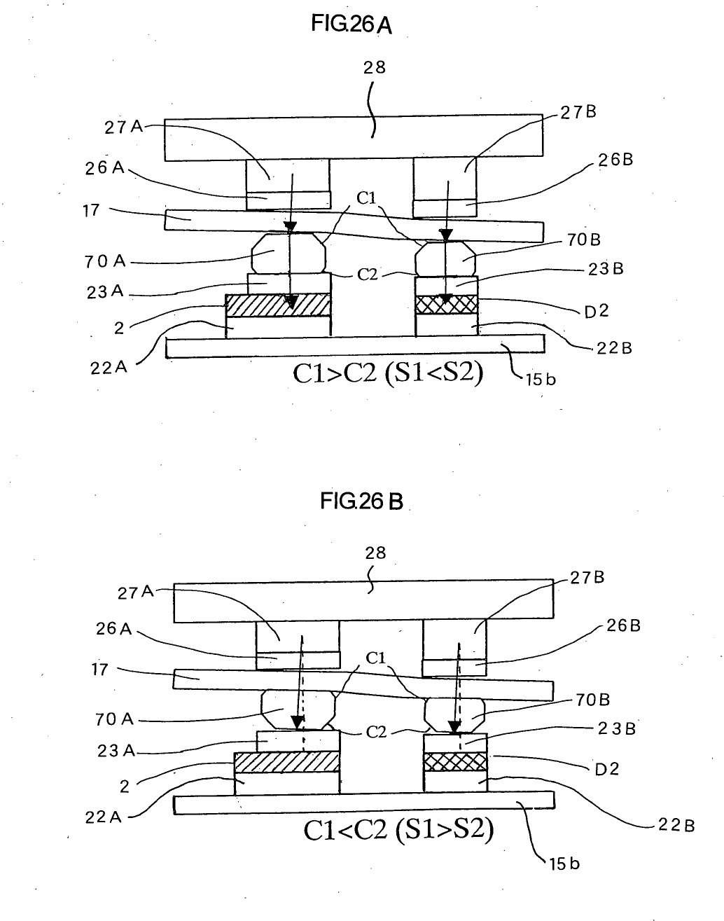

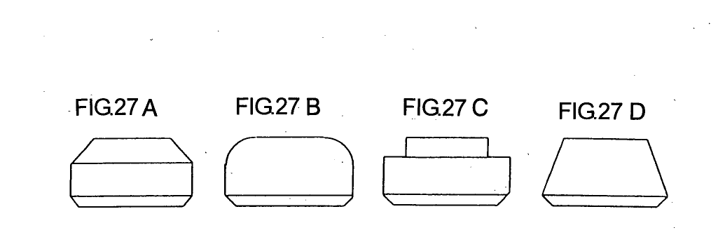

FIG. 26A and FIG. 26B are views illustrating an unbalanced load suppression action, where FIG. 26A shows the case where C1>C2 (S1<S2), and FIG. 26B shows the case where C1<C2 (S1>S2). In the case of FIG. 26A, height differences are absorbed by deformation of the bus bar 17 but slight inclination of the bus bar 17 remains. In this case, force will act on the buffer members 70A and 70B in an inclined direction. However, because of the setting of S1<S2, the upper surface sides of the buffer members 70A and 70B having a higher surface pressure deform, while the lower surface sides having a lower surface pressure remain parallel with respect to the semiconductor chips 2 and D2. It is therefore difficult for an unbalanced load to be generated at the semiconductor chips 2 and D2.

On the other hand, in the case that S1>S2, it is difficult for the direction of force in an inclined direction acting at the buffer members 70A and 70B constituted of a material of a lower Young's modulus to change because S1>S2. Therefore, an unbalanced load can be applied easily to the semiconductor chips 2 and D2.

If S1<S2, the shape of the buffer members 70A and 70B is by no means limited to that described above, and shapes formed by subjecting the outer corners of the upper surfaces to curved surface processing etc. as shown in FIG. 27A to FIG. 27D are also possible. However, it is necessary to ensure that the surface areas S1 provide sufficient surface areas for energizing.

In the example described above, a description is given of the case where press-contact is made with two semiconductor chips of an IGBT and a diode sandwiched between bus bars but application is also possible in the case where there is one semiconductor chip. Namely, there are also cases where press-contact takes place with the upper side bus bar in an inclined state even when there is only one semiconductor chip. In this case, by additionally introducing a buffer member with a lower Young's modulus than the buffer members 23A and 23B, such as the buffer members 70A and 70B, and by then making the upper contact surface area S1 smaller than the lower contact surface area S2, the same results as for that described above can also be achieved.

In the first to fifth embodiments described above, the IGBT 1 and the IGBT 2 may be called semiconductor chips. Further, the buffer members 23A, 23B, 70A and 70B may be referred to as conductive members, the parts 230 of the buffer members 23A and 23B may be referred to as extending sections, the bent sections B and 23c may be referred to as deformed sections, and the terminals 16a and 17a may be referred to as externally derived terminals. It is also possible to refer to the IGBTs 1 and 2 and the diodes D1 and D2 as semiconductor chips, and to the auxiliary cooling members 26A and 26B and the resilient members 27A and 27B as pressing members.

According to the first to fifth embodiments described above, the bus bars 17, 15d and 410 are erected on the front surface side of the semiconductor chips and are press-connected to the semiconductor chips. It is therefore possible to omit a connection operation using wire bonding so that manufacturing efficiency can be improved and it is possible to make the semiconductor device small.

The above-described embodiments are examples, and various modifications can be made without departing from the scope of the invention.

What is claimed is:

1. A semiconductor device comprising:
a first semiconductor chip formed with a front side electrode and a reverse side electrode;
a second semiconductor chip formed with a front side electrode and a reverse side electrode;
a first bus bar on which the first semiconductor chip is mounted so as the reverse side electrode of the first semiconductor chip to be connected thereto;
a second bus bar, arranged horizontally with respect to the first bus bar, on which the second semiconductor chip is mounted so as the reverse side electrode of the second semiconductor chip to be connected thereto;
a third bus bar that is press-connected to the front side electrode of the first semiconductor chip;
a fourth bus bar that is press-connected to the front side electrode of the second semiconductor chip; and
a connecting section that electrically connects the first bus bar and the fourth bus bar.

2. A semiconductor device according to claim 1, wherein:
the first bus bar, the fourth bus bar and the connecting section are formed integrally by bending a single conducting plate.

3. A semiconductor device according to claim 2, wherein:
the first bus bar and the fourth bus bar are linked so as to be capable of relative displacement in a vertical direction at a time of pressing.

4. A semiconductor device according to claim 3, further comprising:
a deforming section provided at the connecting section, that deforms at the time of pressing so as to enable the relative displacement of the first bus bar and the fourth bus bar in the vertical direction.

5. A semiconductor device according to claim 1, wherein:
a part of the first bus bar is press-connected to the fourth bus bar.

6. A semiconductor device comprising:
a first semiconductor chip formed with a front side electrode and a reverse side electrode;
a second semiconductor chip formed with a front side electrode and a reverse side electrode;
a first bus bar on which the first semiconductor chip is mounted so as the reverse side electrode of the first semiconductor chip to be connected thereto, and on which the second semiconductor chip is mounted so as the front side electrode of the second semiconductor chip to be connected thereto;
a second bus bar that is press-connected to the front side electrode of the first semiconductor chip; and
a third bus bar that is press-connected to the reverse side electrode of the second semiconductor chip.

7. A semiconductor device comprising:
a first semiconductor chip formed with a front side electrode and a reverse side electrode;
a second semiconductor chip formed with a front side electrode and a reverse side electrode;
a first bus bar on which the first semiconductor chip is mounted so as the reverse side electrode of the first semiconductor chip to be connected thereto;
a second bus bar, arranged horizontally with respect to the first bus bar, on which the second semiconductor chip is mounted so as the reverse side electrode of the second semiconductor chip to be connected thereto;
a first conductive member that connects with the front side electrode of the first semiconductor chip and comprises an extending section extending beyond the first semiconductor chip;
a second conductive member that connects with the front side electrode of the second semiconductor chip and comprises an extending section extending to above the first bus bar;
a third bus bar, arranged at a front surface side of the first semiconductor chip, with a part press-connected to the extending section of the first conductive member; and
a fourth bus bar, arranged at a front surface side of the second semiconductor chip, with a part connected with the extending section of the second conductive member and press-connected to the first bus bar.

8. A semiconductor device according to claim 7, wherein:
either press-connecting surfaces of the extending sections or connecting surfaces of the first, third and fourth bus bars press-connected to the extending sections is given an irregular shape.

9. A semiconductor device according to claim 7, further comprising:
deforming sections, provided at the first conductive member and the second conductive member, that deform at a time of pressing the third bus bar and the fourth bus bar to the extending sections so as to enable vertical displacement of the extending sections.

10. A semiconductor device according to claim 1, further comprising:
terminals, provided at the second bus bar and the third bus bar so as to be arranged next to each other, that extend to an outside of the semiconductor device.

11. A semiconductor device according to claim 10, wherein:
the terminals of the second bus bar and the third bus bar extend in a same direction.

12. A semiconductor device according to claim 1, further comprising:
third conductive members provided between the first semiconductor chip and the third bus bar and between the second semiconductor chip and the fourth bas bar to touch the first semiconductor chip and the second semiconductor chip respectively; and
fourth conductive members, sandwiched between the first bus bar and the third conductive member and between the second bus bar and the third conductive member respectively, that have a Young's modulus lower than a Young's modulus of the third conductive members.

13. A semiconductor device according to claim 12, wherein:
each of the fourth conductive members is set in such a manner that an area of a first contact surface that is in contact with one of the third bus bar and the fourth bas bar is smaller than an area of a second contact surface that is in contact with one of the third conductive members.

14. A semiconductor device according to claim 13, wherein:
the area of the first contact surface is set to be smaller than the area of the second contact surface by subjecting an edge of the first contact surface to one of curved-surface processing and chamfering.

15. A semiconductor device comprising:
first, second, third and fourth semiconductor chips formed with electrodes on front and reverse sides;
a first bus bar on which the first and second semiconductor chips are mounted so as the reverse side electrodes to be connected thereto;
a second bus bar, arranged horizontally with respect to the first bus bar, on which the third and fourth semiconductor chips are mounted so as the reverse side electrodes to be connected thereto;
a third bus bar that is press-connected to the front side electrodes of the first and second semiconductor chips;
a fourth bus bar that is press-connected to the front side electrodes of the third and fourth semiconductor chips;
a connecting section that electrically connects the first bus bar and the fourth bus bar;
a first pressing member arranged on the third bus bar so as to press the third bus bar towards the first semiconductor chip;
a second pressing member arranged on the third bus bar so as to press the third bus bar towards the second semiconductor chip;
a third pressing member arranged on the fourth bus bar so as to press the fourth bus bar towards the third semiconductor chip; and
a fourth pressing member arranged on the fourth bus bar so as to press the fourth bus bar towards the fourth semiconductor chip.

16. A semiconductor device according to claim 1, further comprising:
an auxiliary cooling member, arranged on the third bus bar and the fourth bus bar, that comprises an extending section for heat dissipation at a side surface.

17. A semiconductor device according to claim 1, further comprising:
a first casing that is formed with the first bus bar, the fourth bus bar, and the connecting section, and that houses the first semiconductor chip; and
a second casing that is formed with the second bus bar, and that houses the second semiconductor chip.

18. A semiconductor device according to claim 7, further comprising:
a first unit that comprises the first semiconductor chip, the second semiconductor chip, the first bus bar, the second bus bar, the first conductive member, and the second conductive member;
a second unit that comprises the third bus bar and the fourth bus bar; and
a third unit that comprises a projection section to press the third bus bar and the fourth bus bar, wherein:
the second unit is laid on top of the first unit, and the third unit is laid on top of the second unit.
